(19) United States
(12) Patent Application Publication
(10) Pub. No.: US 2008/0179655 A1
(43) Pub. Date: Jul. 31, 2008

(54) NONVOLATILE SEMICONDUCTOR MEMORY DEVICE HAVING MULTI-LAYERED OXIDE/(OXY) NITRIDE FILM AS INTER-ELECTRODE INSULATING FILM AND MANUFACTURING METHOD THEREOF

(76) Inventors: Hirokazu Ishida, Yokohama-shi (JP); Masayuki Tanaka, Yokohama-shi (JP); Yoshio Ozawa, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/020,236

(22) Filed: Jan. 25, 2008

(30) Foreign Application Priority Data
Jan. 25, 2007 (JP) 2007-015175

(51) Int. Cl. H01L 29/423; H01L 21/28

(52) U.S. Cl. 257/316; 438/591; 257/E29.129; 257/E29.132; 257/E21.179

(57) ABSTRACT

A nonvolatile semiconductor memory device includes a first insulator, first conductor, element isolation insulator, second insulator and second conductor. The first insulator is formed on the main surface of a substrate and the first conductor is formed on the first insulator. The element isolation insulator is filled into at least part of both side surfaces of the first insulator in a gate width direction thereof and both side surfaces of the first conductor in a gate width direction thereof and is so formed that the upper surface thereof will be set with height between those of the upper and bottom surfaces of the first conductor. The second insulator includes a three-layered insulating film formed of a silicon oxide film, a silicon oxynitride film and a silicon oxide film formed on the first conductor and element isolation insulator. The second conductor is formed on the second insulator.

### CROSS-REFERENCE TO RELATED APPLICATIONS

This application is based upon and claims the benefit of priority from prior Japanese Patent Application No. 2007-015175, filed Jan. 25, 2007, the entire contents of which are incorporated herein by reference.

### BACKGROUND OF THE INVENTION

1. Field of the Invention

This invention relates to a nonvolatile semiconductor memory device and a manufacturing method thereof, and more particularly, to a nonvolatile semiconductor memory device having a multi-layered oxide/(oxy)nitride film formed of an oxide-nitride-oxide (ONO) film or the like as an inter-electrode insulating film and a manufacturing method thereof.

2. Description of the Related Art

A phenomenon that charges are induced in a floating gate electrode layer of one of adjacent cells due to an increase in the interference between the adjacent cells, that is, due to the presence of charges stored in a floating gate electrode layer of another cell becomes a problem with miniaturization of a nonvolatile semiconductor memory element.

Recently, as an inter-electrode insulating layer of the nonvolatile semiconductor memory element, a multi-layered oxide/(oxy)nitride film is used (for example, refer to Jpn. Pat. Appln. KOKAI Publication No. 2005-223198). Therefore, in order to prevent occurrence of the above interference effect, it becomes necessary to make thin the multi-layered oxide/(oxy)nitride film. This is because the opposed surface areas of the floating gate electrode layers can be made smaller by making the inter-electrode insulating film thin and, as a result, the above interference effect can be suppressed. However, since an electric field in the film becomes stronger if the inter-electrode insulating film is made thin, a problem of an increase in the leakage current and deterioration in the film quality due to electrical stress becomes significant.

Since the inter-electrode insulating film must be formed on amorphous silicon or polysilicon, a film with stable thickness cannot be formed by a method using a thermal oxidation process or nitriding process. Therefore, the inter-electrode insulating film is formed by the CVD method using reactive gas. At this time, impurity is mixed into the inter-electrode insulating film to cause an impurity level therein due to elements contained in the reactive gas. Since a substance which becomes impurity is not contained in the reactive gas, it is difficult for the impurity to be mixed into a film formed by a plasma nitriding method or sputtering film formation method.

The impurity level causes electrons to be trapped by application of a strong electric field and plays a role of alleviating the electric field in the film in some cases, but in most cases, it causes a leakage current to be increased via the impurity level. Further, the impurity is diffused in the later thermal process and gives damages to another film, and therefore, it deteriorates the film characteristic. In addition, the bond of silicon and hydrogen present in the film will be broken by long-term electrical stress occurring at the device operation time and, as a result, the device performance will be degraded.

### BRIEF SUMMARY OF THE INVENTION

According to a first aspect of the present invention, there is provided a nonvolatile semiconductor memory device which includes a first insulating layer formed on the main surface of a semiconductor substrate, a first conductive layer formed on the first insulating layer, an element isolation insulating layer formed to cover at least part of both side surfaces of the first insulating layer in a gate width direction thereof and both side surfaces of the first conductive layer in a gate width direction thereof, an upper surface of the element isolation insulating layer being set with height between those of upper and bottom surfaces of the first conductive layer, a second insulating layer formed on the first conductive layer and element isolation insulating layer and including a three-layered insulating film having a lower insulating film which is a silicon oxide film, an intermediate insulating film which is a silicon oxynitride film and an upper insulating film which is a silicon oxide film, and a second conductive layer formed on the second insulating layer.

According to a second aspect of the present invention, there is provided a manufacturing method of a nonvolatile semiconductor memory device which includes forming a first insulating layer on the main surface of a semiconductor substrate, forming a first conductive layer on the first insulating layer, etching both side surfaces of the first conductive layer and first insulating layer in gate width directions thereof to form trenches, filling an insulating film into at least part of the trenches formed in both side surfaces of the first insulating layer in the gate width direction and both side surfaces of the first conductive layer in the gate width direction to form an element isolation insulating layer whose upper surface is set with height between those of upper and bottom surfaces of the first conductive layer, forming a second insulating layer on the first conductive layer and element isolation insulating layer, and forming a second conductive layer on the second insulating layer, wherein the forming the second insulating film includes forming a lower insulating film which is a silicon oxide film on the first conductive layer and element isolation insulating layer, forming an intermediate insulating film which is a silicon oxynitride film on the lower insulating film by one of a plasma nitriding method and sputtering method and an upper insulating film which is a silicon oxide film on the intermediate insulating film.

### BRIEF DESCRIPTION OF THE SEVERAL VIEWS OF THE DRAWING

FIG. 1 is a cross-sectional view showing one manufacturing step of a nonvolatile semiconductor memory device according to a first embodiment of this invention;

FIG. 2 is a cross-sectional view showing one manufacturing step of the nonvolatile semiconductor memory device following the step of FIG. 1;

FIG. 3 is a cross-sectional view showing one manufacturing step of the nonvolatile semiconductor memory device following the step of FIG. 2;

FIG. 4 is a cross-sectional view showing one manufacturing step of the nonvolatile semiconductor memory device following the step of FIG. 3;

FIG. 5 is a cross-sectional view showing one manufacturing step of the nonvolatile semiconductor memory device following the step of FIG. 4;

FIG. 6 is a cross-sectional view showing one manufacturing step of the nonvolatile semiconductor memory device following the step of FIG. 5;

FIG. 7 is a cross-sectional view taken along the A-A′ line of FIG. 6 and showing one manufacturing step of the nonvolatile semiconductor memory device following the step of FIG. 6;

FIG. 8 is a cross-sectional view showing one manufacturing step of a nonvolatile semiconductor memory device according to a third embodiment of this invention;

FIG. 9 is a cross-sectional view showing one manufacturing step of the nonvolatile semiconductor memory device following the step of FIG. 8;

FIG. 10 is a cross-sectional view showing one manufacturing step of the nonvolatile semiconductor memory device following the step of FIG. 9;

FIG. 11 is a cross-sectional view showing one manufacturing step of the nonvolatile semiconductor memory device following the step of FIG. 10;

FIG. 12 is a cross-sectional view showing another manufacturing step of the nonvolatile semiconductor memory device according to the third embodiment of this invention; and

FIG. 13 is a cross-sectional view showing one manufacturing step of the nonvolatile semiconductor memory device following the step of FIG. 11.

### DETAILED DESCRIPTION OF THE INVENTION

### First Embodiment

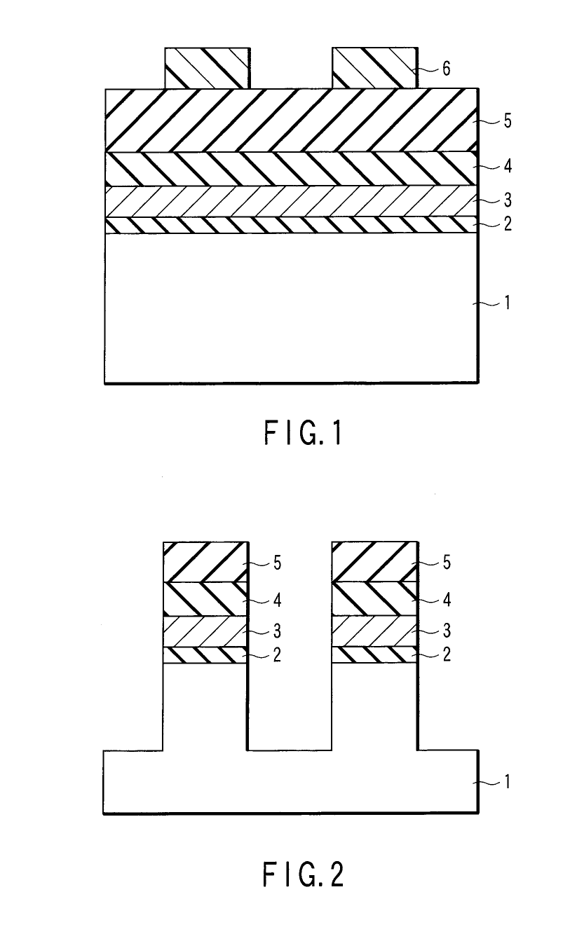

The manufacturing process of a nonvolatile semiconductor memory device according to a first embodiment of this invention is explained with reference to the cross-sectional views of FIGS. 1 to 7.

First, as shown in the cross-sectional view of FIG. 1, a first insulating layer 2 is formed to the thickness of approximately 1 to 15 nm on a p-type silicon substrate 1 (or a p-type well formed on an n-type silicon substrate). For example, the first insulating layer 2 is a silicon oxide film. A first conductive layer 3 (floating gate electrode layer) used as a charge storage layer is formed to the thickness of approximately 10 to 200 nm on the first insulating layer by the chemical vapor deposition (CVD) method. For example, the first conductive layer 3 is an amorphous silicon or polysilicon layer.

Then, a silicon nitride film 4 is formed to the thickness of approximately 50 to 200 nm by the chemical vapor deposition method and a silicon oxide film 5 is formed to the thickness of approximately 50 to 400 nm by the chemical vapor deposition method. After this, photoresist 6 is coated on the silicon oxide film 5 and the photoresist film is patterned by means of an exposure-drawing method to attain the structure shown in the cross-sectional view of FIG. 1.

Next, the silicon oxide film 5 is etched with the photoresist film 6 of FIG. 1 used as an etching mask. The photoresist film 6 is removed after etching and then the silicon nitride film 4 is etched with the silicon oxide film 5 used as a mask. Further, the first conductive layer 3, first insulating layer 2 and silicon substrate 1 are etched to form trenches for element isolation as shown in FIG. 2.

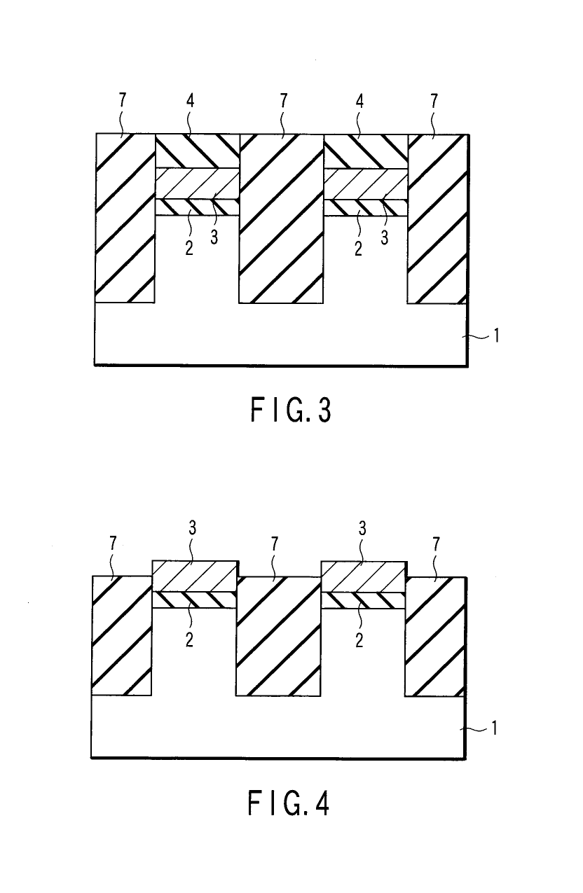

After this, a high-temperature post-oxidation process for elimination of damages of the cross section formed by etching is performed. Then, filling insulating films 7 for element isolation formed of a silicon oxide film or the like are formed to the thickness of 200 to 1500 nm and filled into the element isolation trenches. Further, the density of the insulating films 7 for element isolation is enhanced by performing a high-temperature thermal process in a nitrogen atmosphere or oxygen atmosphere. The resultant semiconductor structure is made flat with the silicon nitride film 4 used as a stopper by the chemical mechanical polishing (CMP) process and the structure shown in FIG. 3 is obtained.

Next, the silicon oxide films 7 (filling insulating films) are etched by means of a method capable of performing an etching process with a selective ratio with respect to the silicon nitride film 4. In the present embodiment, as shown in FIG. 4, a case wherein the silicon oxide films 7 are etched so that the upper surface thereof after etching will reach the height which is almost equal to half the thickness of the first conductive layer 3 is shown. Then, the structure shown in FIG. 4 is obtained by removing the silicon nitride films 4 by means of a method for performing an etching process with a certain selective ratio with respect to the silicon oxide film 7.

In this case, the upper surface of the insulating film 7 for element isolation is set with the height between those of the upper and bottom surfaces of the first conductive layer 3 and the structure is so formed that the upper surface of the first conductive layer 3 projects from the upper surface of the insulating film 7 for element isolation. The structure is so formed as to increase the contact area between the first conductive layers 3 and an inter-electrode insulating film 8 which will be formed later.

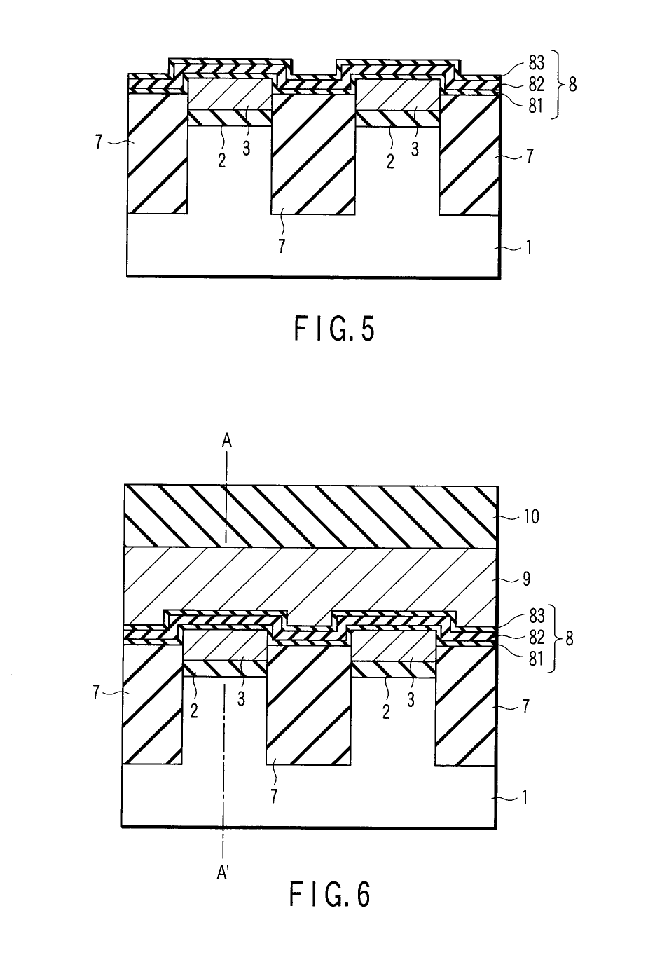

Next, as shown in FIG. 5, an inter-electrode insulating film 8 (second insulating layer) is formed on a substrate with the structure of FIG. 4. The inter-electrode insulating film 8 is a multi-layered insulating film formed of three-layered insulating films 81 to 83.

The structure of FIG. 5 is formed by the following procedure.

First, a silicon oxide film 81 (lower insulating film) is formed with the thickness of 0.5 to 15 nm on the substrate having the structure of FIG. 4 by means of the CVD method. Then, a silicon oxynitride film 82 (intermediate insulating film) is formed with the thickness of 0.5 to 5 nm on the silicon oxide film 81 by means of the plasma nitriding method. Finally, a silicon oxide film 83 (upper insulating film) is formed with the thickness of 0.5 to 10 nm on the silicon oxynitride film 82 by means of the CVD method and thus the inter-electrode insulating film 8 shown in FIG. 5 is formed.

Now, a method for forming the silicon oxynitride film 82 is explained in detail. The silicon oxynitride film 82 is formed in a nitrogen and argon atmosphere by means of the plasma nitriding method. At this time, since the silicon oxynitride film 82 is formed by nitriding the silicon oxide film 81, it becomes an oxynitride film containing oxygen of 10% or more. Since the dielectric constant of the oxynitride film containing oxygen of 10% or more is smaller than that of the nitride film, the degree of the electrical interference effect occurring between the first conductive layers 3 of adjacent cells which sandwich the insulating film 7 can be sufficiently suppressed.

The wafer temperature at the film formation time is 350 to 600° C. and the chamber pressure at the film nitridation time is 50 mTorr to 2 Torr. Since the silicon oxynitride film 82 formed by plasma nitriding does not contain hydrogen and chlorine atoms contained in hexachlorodisilane (HCD), tetrachlorosilane (TCS), dichlorosilane (DCS), silane (SiH₄) or the like used as raw material gas for film formation by the CVD method, a film with the atom concentrations of hydrogen and chlorine of 1.0×10¹⁹ atoms/cm³ or less is formed.

Since the number of trap levels formed by chlorine is significantly reduced when the chlorine concentration is set as low as 1.0×10¹⁹ atoms/cm³ or less in comparison with a case wherein the chlorine concentration is set higher than 1.0×10¹⁹ atoms/cm³, a leakage current caused via the trap level can be suppressed. Further, the influence given by chlorine which is diffused in the thermal process at the device element formation time performed later and giving damages to the oxide film can be suppressed.

Further, hydrogen is present in the form of Si—H bond in the nitride film. The Si—H bonds are broken by electrical stress caused at the device element usage time, dangling bonds of Si are formed and the threshold value fluctuates and, as a result, the reliability of the element is significantly lowered. Since the number of Si—H bonds is significantly reduced when the hydrogen concentration is set as low as 1.0×10¹⁹ atoms/cm³ or less in comparison with a case wherein the hydrogen concentration is set higher than 1.0×10¹⁹ atoms/cm³, the influence that the Si—H bonds are broken can be suppressed. As a result, a lowering in the reliability of the element can be suppressed.

Therefore, the element characteristic in which the leakage current is small and the reliability is less degraded can be attained by forming the silicon oxynitride film 82 by plasma nitriding.

Further, if the silicon oxynitride film 82 is formed by plasma nitriding, the upper portion of the silicon oxide film 81 formed on the first conductive layer 3 is sufficiently nitrided since a large number of nitride radicals collide therewith. On the other hand, however, since not so many nitride radicals collide with the silicon oxide film 81 which covers the side surface portion of the first conductive layer 3, the nitrogen atom concentration of part of the silicon oxynitride film 82 which is formed upside the first conductive layer 3 becomes lower than that of part of the silicon oxynitride film 82 which is formed above the first conductive layer 3.

In other words, the oxygen atom concentration of part of the silicon oxynitride film 82 which covers the side surface portion of the first conductive layer 3 is higher than that of part of the silicon oxynitride film 82 which is formed above the upper portion of the first conductive layer 3.

Therefore, since the nitrogen atom concentration of part of the silicon oxynitride film 82 which is formed above the first conductive layer 3 is high, the dielectric constant thereof is made high. Since the physical film thickness can be made thick by increasing the dielectric constant, the leakage current can be reduced. At the same time, since trap levels caused by nitrogen atoms function as electron traps, the effect that the electric field is alleviated and the leakage current is reduced can be expected.

Further, since the dielectric constant of part of the silicon oxynitride film 82 which is formed above the side surfaces of the first conductive layer 3 and in which the nitrogen atom concentration is relatively lower than that of part of the silicon oxynitride film 82 which is formed above the upper surface of the first conductive layer 3, that is, the oxygen atom concentration is higher and dielectric constant is small, the electrical interference effect caused between the first conductive layers 3 of adjacent cells which sandwich the insulating film 7 can be suppressed.

Then, as shown in FIG. 6, for example, a second conductive layer 9 formed of polysilicon or amorphous silicon is formed to the thickness of 10 to 200 nm on the inter-electrode insulating film 8. The second conductive layer 9 is used as a control gate electrode in the nonvolatile semiconductor memory device. A mask member 10 is formed on the second conductive layer 9 and the structure shown in the cross-sectional view of FIG. 6 is obtained.

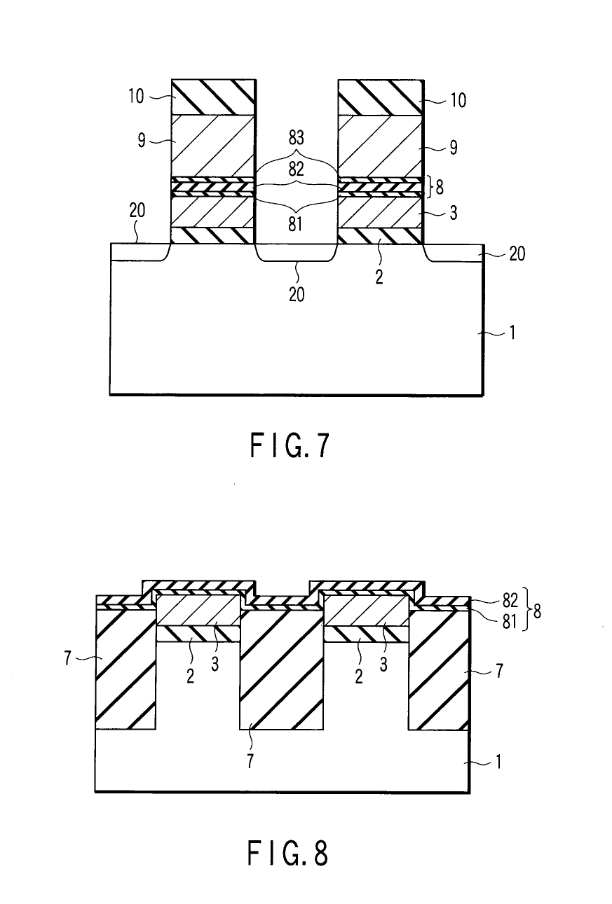

After this, resist is coated on the mask member 10 (not shown) and then the resist film is patterned by an exposure-drawing method. A process is performed with the resist film used as a mask to etch and remove the mask member 10, second conductive layer 9, inter-electrode insulating film 8 (second insulating layer), first conductive layer 3 and first insulating layer 2 (not shown). Further, when the resist film is removed, the structure of FIG. 7 is obtained as the cross-sectional view taken along the A-A′ line of FIG. 6 in a direction perpendicular to the drawing sheet. Then, source and drain regions 20 are formed by ion-implantation in the surface areas of the substrate 1 corresponding to the bottom portions of the etched regions of FIG. 7.

In the present embodiment, a case of the three-layered structure formed of an oxide-nitride-oxide (ONO) film as the inter-electrode insulating film 8 is explained. However, this invention is not limited to this case. For example, in a case of an inter-electrode insulating film in which SiN films are formed on both of the upper and lower portions of the three-layered structure, that is, between the first conductive layer 3 and the silicon oxide film 81 and between the second conductive layer 9 and the silicon oxide film 83 to form an NONON structure or in a case of an inter-electrode insulating film having an SiN film formed on one of the above interfaces, the same effect can be attained.

### Second Embodiment

The manufacturing process of a nonvolatile semiconductor memory device according to a second embodiment of this invention is explained.

First, the structure of FIG. 4 is formed by the same process as that of the first embodiment.

First, as shown in FIG. 5, an inter-electrode insulating film 8 (second insulating layer) is formed on the substrate having the structure of FIG. 4. The inter-electrode insulating film 8 is a multi-layered insulating film formed of three-layered insulating films 81 to 83. The structure of FIG. 5 in the present embodiment is formed by the following procedure unlike the case of the first embodiment.

First, a silicon oxide film 81 (lower insulating film) is formed to the thickness of 0.5 to 10 nm on the substrate with the structure of FIG. 4 by means of the CVD method. Then, a silicon oxynitride film 82 (intermediate insulating film) is formed to the thickness of 0.5 to 15 nm on the silicon oxide film 81 by means of the sputtering method. Finally, a silicon oxide film 83 (upper insulating film) is formed to the thickness of 0.5 to 10 nm on the silicon oxynitride film 82 by means of the CVD method and thus the inter-electrode insulating film 8 shown in FIG. 5 is formed.

Now, a method for forming the silicon oxynitride film 82 is explained in detail. The silicon oxynitride film 82 is formed in an oxygen and nitrogen atmosphere by means of the sputtering method. At this time, since oxygen and nitrogen are present in the chamber atmosphere, the silicon oxynitride film 82 becomes an oxynitride film containing oxygen of 10% or more. Since the dielectric constant of the oxynitride film containing oxygen of 10% or more is smaller than that of the nitride film, the degree of the electrical interference effect occurring between the first conductive layers 3 of adjacent cells which sandwich the insulating film 7 can be suppressed.

The film formation process is performed with the RF power of 3 kW and the wafer temperature of 300° C. at the film deposition time. Since the silicon oxynitride film 82 formed by the sputtering film formation process does not contain hydrogen and chlorine atoms contained in hexachlorodisilane (HCD), tetrachlorosilane (TCS), dichlorosilane (DCS), silane (SiH₄) or the like used as raw material gas for film formation by the CVD method, a film with the hydrogen and chlorine atom concentrations which is as low as 1.0×10¹⁹ atoms/cm³ or less is formed.

A leakage current caused by the trap levels formed by chlorine can be suppressed when the chlorine concentration is set as low as 1.0×10¹⁹ atoms/cm³ or less. Further, the influence given by chlorine which is diffused in the thermal process at the device element deposition time performed later and giving damages to the oxide film can be suppressed.

Further, Si—H bonds formed by means of hydrogen in the nitride film are broken by electrical stress caused at the device element usage time, dangling bonds of Si are formed and the threshold value fluctuates and, as a result, the reliability of the element is significantly lowered. Since the number of Si—H bonds is reduced when the hydrogen concentration is set as low as 1.0×10¹⁹ atoms/cm³ or less, the influence caused by breaking the Si—H bonds can be suppressed and thus an influence exerted on the reliability of the element can be suppressed.

Therefore, if the silicon oxynitride film 82 is formed by the sputtering process, the element characteristic in which the leakage current is small and a lowering in the reliability is suppressed can be attained.

The process performed after this is the same as that of the first embodiment as explained with reference to FIGS. 6 and 7.

In the present embodiment, a case of the three-layered structure formed of an oxide-nitride-oxide (ONO) film as the inter-electrode insulating film 8 is explained. However, this invention is not limited to this case. For example, in a case of an inter-electrode insulating film in which SiN films are formed on both of the upper and lower portions of the three-layered structure, that is, between the first conductive layer 3 and the silicon oxide film 81 and between the second conductive layer 9 and the silicon oxide film 83 to form an NONON structure or in a case of an inter-electrode insulating film having an SiN film formed on one of the above interfaces, the same effect can be attained.

Further, in the present embodiment, an example in which the oxide film 83 of the inter-electrode insulating film 8 is formed by means of the CVD process is explained, but it can be formed by means of another formation method. For example, a Top-SiO₂ film can be formed by oxidizing an ON film formed of the silicon oxynitride film 82 and silicon oxide film 81 formed on the first conductive layer 3 and can be used as the silicon oxide film 83.

In addition, in the present embodiment, since a silicon oxynitride film 82 with thick film thickness can be formed by the sputtering film formation method, the above method can be used. The same effect as described above can be attained by means of an inter-poly insulating film formed by the above method.

### Third Embodiment

The manufacturing process of a nonvolatile semiconductor memory device according to a third embodiment of this invention is explained.

First, the structure of FIG. 4 is formed by the same process as that of the first and second embodiments.

Then, as shown in FIG. 5, an inter-electrode insulating film 8 (second insulating layer) is formed on the substrate having the structure of FIG. 4. The inter-electrode insulating film 8 is a multi-layered insulating film formed of three-layered insulating films 81 to 83. The structure of FIG. 5 in the present embodiment is formed by the following procedure.

First, as shown in FIG. 8, a silicon oxide film 81 (lower insulating film) is formed with the thickness of 0.5 to 15 nm on the substrate having the structure of FIG. 4 by means of the CVD method. Then, a silicon oxynitride film 82 (intermediate insulating film) is formed to the thickness of 0.5 to 5 nm on the silicon oxide film 81 by means of the plasma nitriding method.

Since the silicon oxynitride film 82 is formed by the plasma nitriding method like the case of the first embodiment, it becomes an oxynitride film containing oxygen of 10% or more. Since the dielectric constant of the oxynitride film containing oxygen of 10% or more is smaller than that of the nitride film, the degree of the electrical interference effect occurring between the first conductive layers 3 of adjacent cells which sandwich the insulating film 7 can be suppressed.

Further, like the first and second embodiments, since both of the hydrogen atom concentration and chlorine atom concentration of the oxynitride film 82 are set as low as 1.0×10¹⁹ atoms/cm³ or less, the element characteristic in which the leakage current is small and a lowering in the reliability is suppressed can be attained.

Further, since the silicon oxynitride film 82 is formed by the plasma nitriding method like the case of the first embodiment, the nitrogen atom concentration of part of the oxynitride film 82 which is formed above the first conductive layer 3 becomes higher than the nitrogen atom concentration of part of the oxynitride film 82 which is formed above the side surface portion of the first conductive layer 3.

In other words, the oxygen atom concentration of part of the silicon oxynitride film 82 which covers the side surface portion of the first conductive layer 3 is higher than that of part of the silicon oxynitride film 82 which is formed above the upper portion of the first conductive layer 3.

Therefore, a leakage current flowing through the inter-electrode insulating film 8 can be reduced and, at the same time, the electrical interference effect caused between the first conductive layers 3 of adjacent cells which sandwich the insulating film 7 can be suppressed.

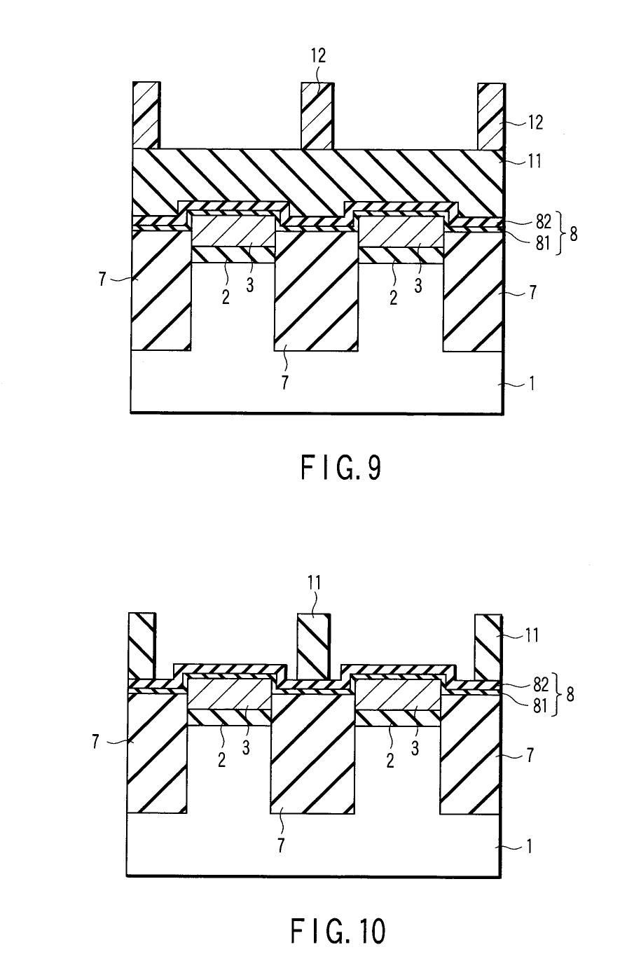

Then, as shown in FIG. 9, a silicon oxide film 11 is formed to the thickness of approximately 50 to 400 nm by the chemical vapor deposition method. After this, photoresist 12 is coated on the silicon oxide film 11 and the photoresist film 12 is patterned by an exposure-drawing process to attain the structure shown in the cross-sectional view of FIG. 9.

Next, the silicon oxide film 11 is etched with the photoresist film 12 of FIG. 9 used as an etching-resistant mask and then the photoresist film 12 is removed to attain the structure of FIG. 10.

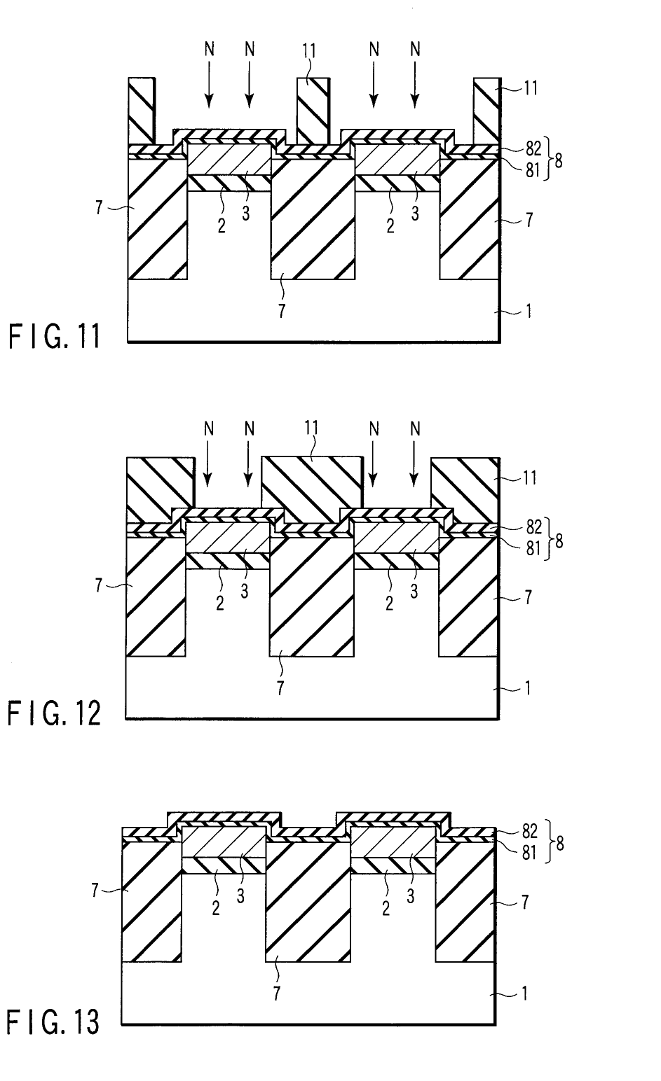

After this, as shown in FIG. 11, nitrogen is ion-implanted with the silicon oxide film 11 used as a mask. As a result, nitrogen is doped into that part of the silicon oxynitride film 82 which is formed above the first conductive layer 3 other than that part of the silicon oxynitride film 82 which is masked by the silicon oxide film 11 and formed above the insulating film 7.

In this case, as shown in FIG. 12, it is possible to form a larger mask of the silicon oxide film 11, mask portions of the silicon oxynitride film 82 which cover the side surface portions of the first conductive layers 3 and dope nitrogen only into portions of the silicon oxynitride film 82 which are formed above the first conductive layers 3.

In this embodiment, nitrogen is doped by ion-implantation, but nitrogen can be doped by plasma nitriding.

In the present embodiment, the nitrogen atom concentration of that part of the silicon oxynitride film 82 which is formed above the first conductive layer 3 can be made further higher than that of part of the silicon oxynitride film 82 which is formed above the element isolation insulating film 7 and that of part of the silicon oxynitride film 82 which covers the side surfaces of the first conductive layer 3 by performing the above nitrogen doping process.

Thus, the effect that a leakage current is further reduced can be expected. Since the nitrogen atom concentration of part of the silicon oxynitride film 82 which is formed above the element isolation insulating film 7 and the nitrogen atom concentration of part of the silicon oxynitride film 82 which covers the side surfaces of the first conductive layer 3 are relatively lower than that of a portion thereof lying above the first conductive layer 3, the dielectric constants thereof are relatively smaller. Therefore, the electrical interference effect caused between the first conductive layers 3 of adjacent cells which sandwich the insulating film 7 can be suppressed.

Then, the silicon oxide film 11 used as the mask is removed by wet etching and the cross-sectional structure of FIG. 13 is obtained. Further, a silicon oxide film 83 (upper insulating film) is formed with the thickness of 0.5 to 10 nm on the silicon oxynitride film 82 by the CVD method and the inter-electrode insulating film 8 shown in FIG. 5 is formed.

The process performed after this is the same as that of the first and second embodiments as explained with reference to FIGS. 6 and 7.

In the present embodiment, a case wherein nitrogen is doped into portions of the silicon oxynitride film 82 which are formed above the first conductive layers 3 is explained. However, an attempt can be made to dope oxygen only into portions of the silicon oxynitride film 82 which are formed above the element isolation insulating films 7 by ion-implantation or annealing in an oxygen atmosphere and plasma oxidation and further reduce the interference effect between the adjacent cells.

Thus, since the same relative relation with the nitrogen and oxygen atom concentrations of portions of the silicon oxynitride film 82 which respectively lie above the first conductive layers 3 and element isolation insulating films 7 can be attained, the same effect as that of the above case can be expected.

In the present embodiment, a case of the three-layered structure formed of an oxide-nitride-oxide (ONO) film as the inter-electrode insulating film 8 is explained. However, this invention is not limited to this case. For example, in a case of an inter-electrode insulating film in which SiN films are formed on both of the upper and lower portions of the three-layered structure, that is, between the first conductive layer 3 and the silicon oxide film 81 and between the second conductive layer 9 and the silicon oxide film 83 to form an NONON structure or in a case of an inter-electrode insulating film having an SiN film formed on one of the above interfaces, the same effect can be attained.

As described above, in the first to third embodiments, at least one of the nitride films is an oxynitride film containing oxygen and is a film containing a small amount of hydrogen and chlorine which are impurities in the structure of a multi-layered oxide/(oxy)nitride film such as an oxide-nitride-oxide (ONO) film and a nitride-oxide-nitride-oxide-nitride (NONON) film used as the inter-electrode insulating film of the nonvolatile semiconductor memory element.

The oxynitride film formed above the floating gate electrode layer can cause a leakage current to be reduced if the nitrogen atom concentration thereof is enhanced. Further, the oxynitride film formed above the side surface portion of the floating gate electrode layer or the element isolation insulating film can cause the interference effect between the floating gate electrode layers to be suppressed if the dielectric constant thereof is lowered by enhancing the oxygen atom concentration thereof.

A leakage current flowing via the trap levels caused by chlorine is reduced by lowering the impurity concentrations of chlorine and hydrogen in the oxynitride film and degradation in the reliability of the element in a long term caused by removal of hydrogen can be suppressed.

As described above, according to one aspect of this invention, it is possible to provide a nonvolatile semiconductor memory device and a manufacturing method thereof capable of suppressing the interference effect between the floating gate electrodes, reducing a leakage current flowing through the inter-electrode insulating film and preventing deterioration in the element.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory device comprising:
a first insulating layer formed on a main surface of a semiconductor substrate,
a first conductive layer formed on the first insulating layer,
an element isolation insulating layer formed to cover at least part of both side surfaces of the first insulating layer in a gate width direction thereof and both side surfaces of the first conductive layer in a gate width direction thereof, an upper surface of the element isolation insulating layer being set with height between those of upper and bottom surfaces of the first conductive layer,
a second insulating layer formed on the first conductive layer and element isolation insulating layer and including a three-layered insulating film having a lower insulating film which is a silicon oxide film, an intermediate insulating film which is a silicon oxynitride film and an upper insulating film which is a silicon oxide film, and
a second conductive layer formed on the second insulating layer.

2. The nonvolatile semiconductor memory device according to claim 1, wherein concentrations of hydrogen atoms and chlorine atoms contained in the intermediate insulating film are not higher than 1.0×10¹⁹ atoms/cm³.

3. The nonvolatile semiconductor memory device according to claim 2, wherein a percentage of oxygen atoms contained in the intermediate insulating film is not less than 10% of a total number of atoms.

4. The nonvolatile semiconductor memory device according to claim 1, wherein nitrogen atom concentration in part of the intermediate insulating film which is formed above the upper surface of the first conductive layer is higher than nitrogen atom concentration in part of the intermediate insulating film which is formed above the both side surfaces of the first conductive layer in the gate width direction.

5. The nonvolatile semiconductor memory device according to claim 1, wherein nitrogen atom concentration in part of the intermediate insulating film which is formed above the first conductive layer is higher than nitrogen atom concentration in part of the intermediate insulating film which is formed above the element isolation insulating layer.

6. The nonvolatile semiconductor memory device according to claim 1, wherein oxygen atom concentration in part of the intermediate insulating film which is formed on the element isolation insulating layer is higher than oxygen atom concentration in part of the intermediate insulating film which is formed above the first conductive layer.

7. The nonvolatile semiconductor memory device according to claim 1, wherein the second insulating layer has a structure which further includes a first silicon nitride film formed between the first conductive layer and the lower insulating film and a second silicon nitride film formed between the second conductive layer and the upper insulating film.

8. The nonvolatile semiconductor memory device according to claim 1, wherein the second insulating layer further includes one of a silicon nitride film formed between the first conductive layer and the lower insulating film and a silicon nitride film formed between the second conductive layer and the upper insulating film.

9. A manufacturing method of a nonvolatile semiconductor memory device comprising:
forming a first insulating layer on a main surface of a semiconductor substrate,
forming a first conductive layer on the first insulating layer,
etching both side surfaces of the first conductive layer and first insulating layer in gate width directions thereof to form trenches,
filling an insulating film into at least part of the trenches formed in both side surfaces of the first insulating layer in the gate width direction and both side surfaces of the first conductive layer in the gate width direction to form an element isolation insulating layer whose upper surface is set with height between those of upper and bottom surfaces of the first conductive layer,
forming a second insulating layer on the first conductive layer and element isolation insulating layer, and
forming a second conductive layer on the second insulating layer,
wherein the forming the second insulating film includes forming a lower insulating film which is a silicon oxide film on the first conductive layer and element isolation insulating layer, forming an intermediate insulating film which is a silicon oxynitride film on the lower insulating film by one of a plasma nitriding method and sputtering method, and forming an upper insulating film which is a silicon oxide film on the intermediate insulating film.

10. The manufacturing method of the nonvolatile semiconductor memory device according to claim 9, wherein concentrations of hydrogen atoms and chlorine atoms contained in the intermediate insulating film are not higher than 1.0×10¹⁹ atoms/cm³.

11. The manufacturing method of the nonvolatile semiconductor memory device according to claim 10, wherein a percentage of oxygen atoms contained in the intermediate insulating film is not less than 10% of a total number of atoms.

12. The manufacturing method of the nonvolatile semiconductor memory device according to claim 9, wherein the forming the intermediate insulating film is performed by the plasma nitriding method in an atmosphere containing nitrogen and argon to nitride the silicon oxide film which is the lower insulating film and form the silicon oxynitride film.

13. The manufacturing method of the nonvolatile semiconductor memory device according to claim 9, wherein the forming the intermediate insulating film is to form the silicon oxynitride film on the lower insulating film by the sputtering method.

14. The manufacturing method of the nonvolatile semiconductor memory device according to claim 9, wherein nitrogen atom concentration in part of the intermediate insulating film which is formed above the first conductive layer is higher than nitrogen atom concentration in part of the intermediate insulating film which is formed above both side surfaces of the first conductive layer in the gate width direction.

15. The manufacturing method of the nonvolatile semiconductor memory device according to claim 9, wherein nitrogen atom concentration in part of the intermediate insulating film which is formed above the first conductive layer is higher than nitrogen atom concentration in part of the intermediate insulating film which is formed above the element isolation insulating layer.

16. The manufacturing method of the nonvolatile semiconductor memory device according to claim 9, wherein oxygen atom concentration in part of the intermediate insulating film which is formed above the element isolation insulating layer is higher than oxygen atom concentration in part of the intermediate insulating film which is formed above the first conductive layer.

17. The manufacturing method of the nonvolatile semiconductor memory device according to claim 9, further comprising forming a first silicon nitride film on the first conductive layer after the forming the element isolation insulating layer and before the forming the lower insulating film, and forming a second silicon nitride film after the forming the upper insulating film and before the forming the second conductive layer.

18. The manufacturing method of the nonvolatile semiconductor memory device according to claim 9, further comprising forming a silicon nitride film in one of a period after the forming the element isolation insulating layer and before the forming the lower insulating film and a period after the forming the upper insulating film and before the forming the second conductive layer.
